(19) United States
(12) Patent Application Publication
(10) Pub. No.: US 2006/0093754 A1
(43) Pub. Date: May 4, 2006

(54) System and method for supplying precursor gases to an implantation tool

(76) Inventors: Christian Krueger, Liegau-Augustusbad (DE); Rastislav Kocis, Radebeul (DE)

Correspondence Address: WILLIAMS, MORGAN & AMERSON, 10333 RICHMOND, SUITE 1100, HOUSTON, TX, 77042, US

(21) Appl. No.: 11/145,591

(22) Filed: Jun. 6, 2005

(30) Foreign Application Priority Data
Oct. 29, 2004 (DE) 10 2004 052 580.3

(51) Int. Cl. C23C 14/00; H01J 7/24; C23C 16/00; H05B 31/26

(52) U.S. Cl. 427/523; 118/715; 315/111.81

(57) ABSTRACT

An improved supply system for an ion source of an ion implantation tool and a method of operating the same is provided. By using a buffer volume between an SDS gas bottle and the ion source, stability of the gas flow to the ion source is significantly enhanced, while at the same time nearly all of the gas contents in the gas bottle may be available during operation of the ion implantation tool.

### BACKGROUND OF THE INVENTION

1. Field of the Invention

The present invention generally relates to the fabrication of microstructures, such as integrated circuits, and, more particularly, to ion implantation tools and peripheral components thereof which are required to produce well-defined dopant profiles in device regions.

2. Description of the Related Art

The fabrication of complex microstructures, such as sophisticated integrated circuits, requires that a large number of individual process steps be performed to finally obtain the required functionality of the microstructure. Especially in the formation of integrated circuits, the conductivity of specific areas has to be adapted to design requirements. For instance, the conductivity of a semiconductor region may be increased in a well-defined manner by introducing specific impurities, which are also referred to as dopants, and placing some or preferably all of these impurities at lattice sites of the semiconductor crystal.

Commonly, ion implantation is the preferred method for introducing dopants into specified device regions due to the ability to center the impurities around a desired depth and to relatively precisely control the number of dopant atoms implanted into substrates with a repeatability and uniformity of better than approximately ±1%. Moreover, impurities that are introduced by ion implantation have a significantly lower lateral distribution when compared to conventional dopant diffusion processes. Since ion implantation is typically a room temperature process, the lateral profiling of a doped region may in many cases conveniently be achieved by providing a correspondingly patterned photoresist mask layer. These characteristics may render ion implantation currently, and in the near future, the preferred technique to produce doped regions in a semiconductor device.

The implantation of dopants may be accomplished by a plurality of ion implantation tools, which are extremely complex machines requiring a continuous monitoring of the machine characteristics to achieve high efficiency, reliability and machine utilization. An ion implantation tool typically comprises an accelerator tube that is configured and dimensioned to accelerate ions with a specified acceleration voltage, which my typically range from 0 Volts to approximately 200 kV for a typical medium current implanter, and may range to several hundred kV or even to 1 MV or more in high-energy implanters. The implantation tool further comprises an ion source to create a specified ion species, pre-accelerate the created ions and supply them to the accelerator tube. The ion source is typically connected to various peripheral components of which one essential component is a gas supply system that is configured to provide a specified type of precursor gas, from which one or more ion species may be generated within the ion source. In modern ion implantation tools used in the semiconductor industry, special implant dopant precursors are commonly used, which are typically supplied and handled in gas bottles. Many of these precursor gases, such as BF₃, AsH₃, PH₃, etc., are extremely hazardous, and thus require specific measures in handling the gas bottles and the supply system to substantially avoid any environmental contamination with these gases. Hence, an appropriately designed gas supply system in combination with efficient and safe gas bottles are important aspects in operating ion implantation tools in semiconductor facilities. For this reason, gas bottles of increased safety standards have recently been developed, which are referred to as safe delivery source (SDS) bottles.

An SDS gas bottle includes an adsorbent material that is configured to receive and store the precursor gas. Moreover, the gas bottle is held at a pressure level below 1 atmosphere to reduce gas leakage upon occurrence of a gas leak during handling and operating the gas bottle. The SDS gas bottle is connected to the supply system by means of appropriate conduits including valve regimes for supplying the gases as is required by a specified process recipe. The gas flow from the bottle to the ion source is then discontinued when the specific precursor gas is no longer required, for instance, due to a change of the process recipe. When a gas flow between the gas bottle and the ion source is required and the valve regime is correspondingly set, the difference in pressure between the vacuum process chamber of the ion source and the gas bottle forces the release of the precursor gas from the adsorbent material and drives the gas flow. This technique significantly reduces the risk of an accidental release of hazardous gases into the environment. The gas bottles are substantially completely filled with the adsorbent material to provide as much surface area as possible for the storage of the precursor gas. During operation of the gas supply system, it turns out, however, that it is extremely difficult to extract all of the precursor gas from the bottle owing to the restricted gas release rate of the adsorbent material, and thus the adsorbent material remains partially filled with the precursor gas. A further problem arises when the gas bottle is increasingly exhausted, since then the decreasing gas release rate from the adsorbent material may not be sufficient to maintain a stable gas flow for extended time periods. As a consequence of the reduced gas flow stability, the plasma in the ion source may become unstable or may vary and the corresponding plasma fluctuations may significantly affect the operation of the entire ion implantation tool.

As previously pointed out, especially advanced semiconductor devices require highly sophisticated implantation profiles so that process variations caused by gas flow instabilities may not be acceptable and may require a premature change of the respective gas bottles. It turns out, however, that the adsorbent material may hold back up to nearly 10% of the precursor gas initially filled into the bottle, thereby rendering SDS gas bottles as moderately inefficient in view of cost of ownership. Therefore, in semiconductor facilities, frequently a substantially exhausted gas bottle that may be connected to a high current implantation tool, the ion source of which requires a moderately high gas flow of the precursor gas, is disconnected and may then be installed at a medium current implantation tool requiring a significantly lower gas flow. Although this process technique may allow increased utilization of the precursor gas in an SDS gas bottle, the problem of unstable gas flow is only postponed and may now require a premature gas bottle change at the medium current implantation tool. Moreover, an additional change of a gas bottle with extremely hazardous gases is required, thereby not only increasing the risk for environmental contamination, but also increasing the down time of the ion implantation tools.

In view of the above-identified situation, there exists a need for an enhanced apparatus and method for delivering a precursor gas to an ion implantation tool.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique that enables the utilization of a significantly increased amount of precursor gas stored in an SDS gas bottle at a high tool utilization while not unduly increasing the risk of environmental contaminations, which may conventionally be caused by an increased number of gas bottle changes. According to embodiments of the present invention, the initial contents of an SDS gas bottle may be used more efficiently in that an additional gas buffer volume is provided between the SDS gas bottle and the ion source of an implantation tool, thereby significantly increasing the gas flow stability and the amount of gas extracted from the adsorbent material within the SDS gas bottle.

According to a further illustrative embodiment of the present invention, a system comprises an input conduit system adapted to be configured for fluid communication with one or more precursor gas bottles for an ion source of an ion implantation tool. The system further comprises an output conduit system adapted to be configured for fluid communication with the ion source. Moreover, a gas buffer system is provided and is adapted to be configured for fluid communication with the input conduit system and the output conduit system.

According to still a further illustrative embodiment of the present invention, a system comprises an ion implantation tool comprising an ion source and at least one precursor gas bottle containing a precursor gas to be supplied to the ion source. The system further comprises a buffer system for receiving the precursor gas from the at least one gas bottle prior to the precursor gas being supplied to the ion source.

In accordance with yet another illustrative embodiment of the present invention, a method of operating a supply system is provided. The method comprises receiving in a first buffer volume a first precursor gas of an ion implantation tool from a first gas bottle. Moreover, the first precursor gas contained in the first buffer volume is supplied to an ion source of the ion implantation tool.

### BRIEF DESCRIPTION OF THE DRAWINGS

The invention may be understood by reference to the following description taken in conjunction with the accompanying drawings, in which like reference numerals identify like elements, and in which:

FIGS. 1a-1b schematically depict a supply system for precursor gases in accordance with illustrative embodiments of the present invention; and

FIGS. 2a-2c schematically show a supply system including at least two variable gas buffer volumes that receive the same precursor gas in various operating states in accordance with further illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

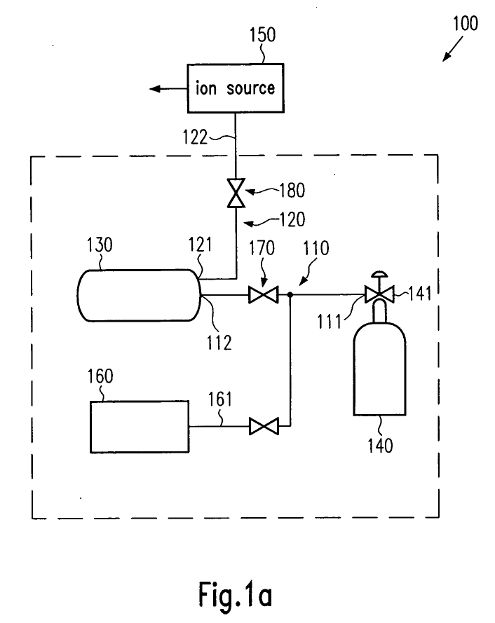

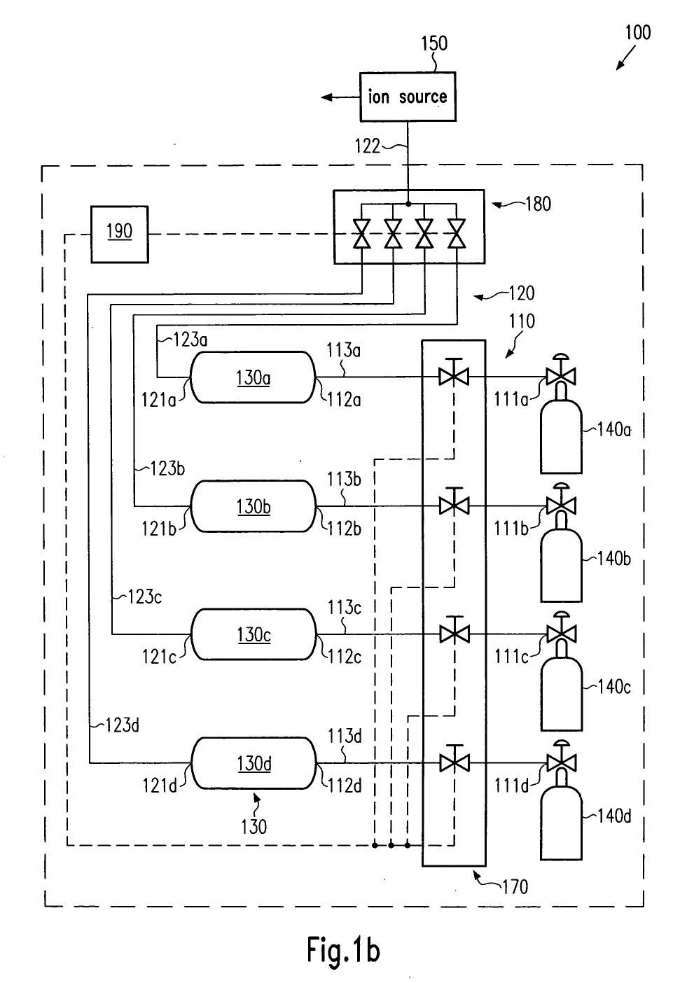

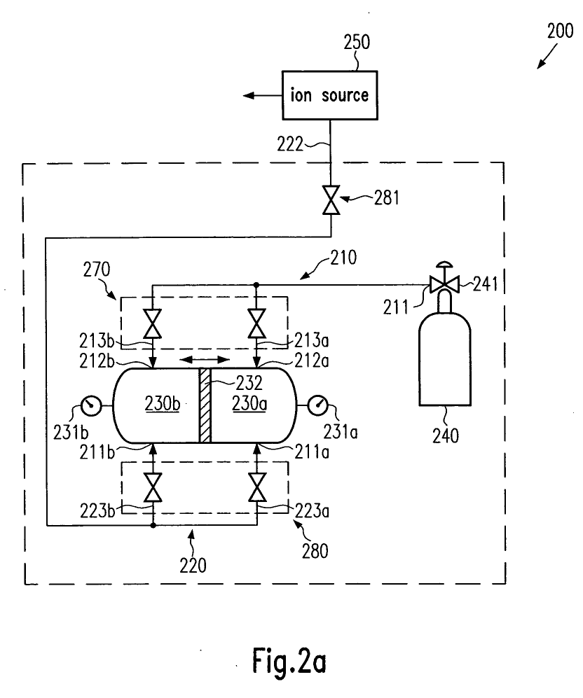

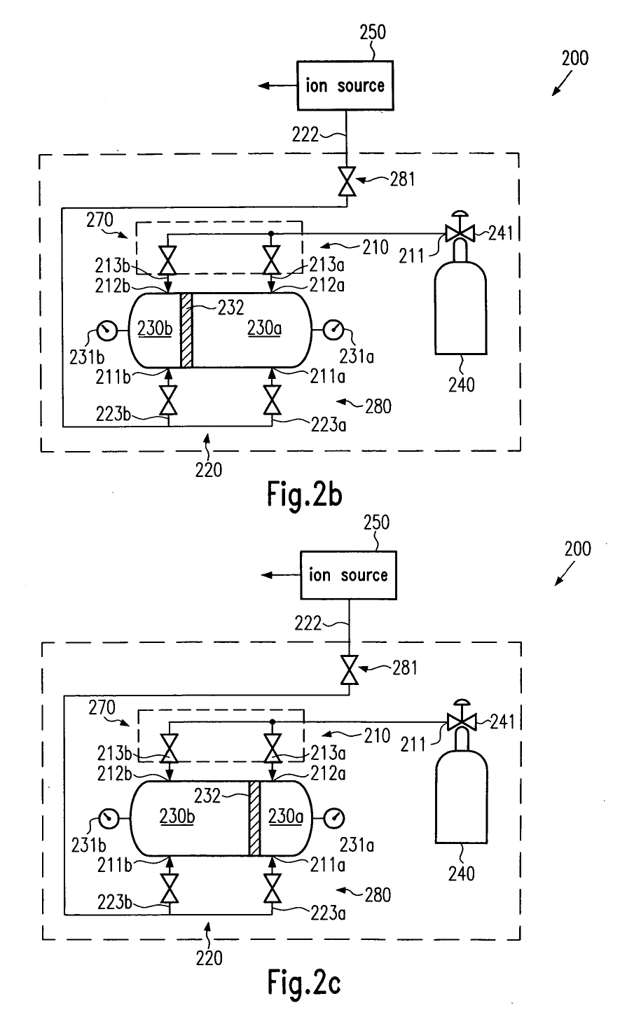

As previously explained, gas flow instabilities within a supply system for an ion source of an implantation tool may significantly affect the overall performance of the implantation tool, and may therefore require a premature change of SDS gas bottles, thereby significantly adding to the cost of ownership. Even if a nearly exhausted SDS gas bottle in a high current ion implantation tool is replaced and is subsequently operated with a medium or low current implantation tool, the same problem arises in these implantation tools, although at a somewhat later stage, while at the same time causing increased down times for the involved implantation tools and additional gas bottle handling steps. These problems encountered in conventional supply systems for ion implantation tools may significantly be relaxed by providing a supply system comprising an additional buffer volume that is connected between the gas bottle and the ion source to allow the precursor gas stored in the adsorbent material of the SDS gas bottle to expand into the buffer volume, while the ion source receives the precursor gas from the buffer volume substantially without short-time fluctuations, even if the SDS gas bottle is substantially exhausted. With reference to FIGS. 1a-1b and 2a-2c, further illustrative embodiments of the present invention will now be described in more detail.

FIG. 1a schematically shows a supply system 100, which is configured to provide a precursor gas as is typically used in modern implantation tools to an ion source 150 of an ion implantation tool (not shown). The supply system 100 comprises an input conduit system 110 having an input end 111 and an output end 112. The input end 111 of the input conduit system 110 is configured to be connectable to a gas bottle 140, which, in one particular embodiment, is an SDS gas bottle. The gas bottle 140 may be equipped with a valve element 141. The supply system 100 further comprises an output conduit system 120 having an input end 121 and an output end 122, which is connected to the ion source 150. The supply system 100 further comprises a gas buffer system 130 including a buffer volume configured to receive a specified precursor gas. That is, the gas buffer system 130 is configured to provide for the mechanical and chemical integrity of the buffer volume as is necessary for any safety requirements in handling extremely hazardous precursor gases. The same holds true for any components of the supply system 100, such as the input conduit system 110 and the output conduit system 120. For example, the gas buffer system 130 may be made of substantially the same materials as are used for manufacturing the container of the gas bottle 140.

Moreover, the gas buffer system 130 is configured to be in fluid communication with the output end 112 of the input conduit system 110 and to be in fluid communication with the input end 121 of the output conduit system 120. For convenience, any sealing means and other mechanical components required for reliably connecting the output end 112 and the input end 121 with the buffer system 130, which are well known in the art, are not shown in FIG. 1a. Moreover, the buffer volume defined by the gas buffer system 130 is, in one illustrative embodiment, selected to have a size that is substantially of the same order of magnitude as the gas volume defined by the gas bottle 140 or the adsorbent material contained therein. For example, the buffer volume defined by the gas buffer system 130 may amount to at least approximately 50% or more of the volume of the gas bottle 140. In one embodiment, the size of the buffer volume may be at least the size of the volume defined by the bottle 140. The supply system 100 may further comprise an input valve unit 170 provided within the input conduit system 110 to control the gas flow between the gas bottle 140 and the gas buffer system 130. In other embodiments, the supply system 100 may further comprise an output valve unit 180 provided within the output conduit system 120 to control the gas flow between the gas buffer system 130 and the ion source 150. It should be appreciated that the valve unit 170 and particularly the valve unit 180 may include a plurality of individual valve elements, measurement devices and the like, as are also used in conventional supply systems. Moreover, other components, such as a purge gas system 160 including a corresponding conduit system 161 may be provided and may be connected to the input conduit system 110 and/or the output conduit system 120 and/or the gas buffer system 130 to allow the flow of a purge gas within the supply system 100 in accordance with process requirements. It should be appreciated that the supply system 100 may include other components, such as additional valve elements and control and measurement devices, which are well known in the art and thus not illustrated in FIG. 1a.

During operation of the supply system 100, the gas bottle 140 is connected to the input end 111 of the input conduit system 110 and the valve 141 is operated to provide a fluid connection from the interior volume of the gas bottle 140 to the input end 111. The input valve unit 170 may be configured such that it may be switched from a closed state, when no gas bottle is connected to the input end 111, to an open state, when the gas bottle 140 is connected and the valve 141 is in its open state. For this purpose, the input valve unit 170 may comprise a controllable valve element that may be opened and closed, or that may allow a proportional adjustment of the flow resistance from the gas bottle 140 to the buffer system 130. In one illustrative embodiment, the input valve unit 170 may comprise a check valve that allows gas flow from the input end 111 to the output end 112, but prevents a back flow of gas from the output end 112 to the input end 111. Consequently, as long as the gas pressure at the input end 111 is higher compared to the output end 112, the check valve allows fluid flow from the bottle 140 to the buffer system 130, but prevents back flow of gas into the bottle 140 when the gas pressure in the bottle 140 is lower than in the buffer system 130. For instance, the buffer system 130 may comprise a component for pressurizing the gas within the gas buffer volume 130 at a certain state of operation, for instance, when the pressure within the gas buffer volume 130 is below a specified threshold. In this case, a substantially stable gas flow may be maintained in the output conduit system 120 without driving precursor gas from the buffer 130 back into the gas bottle 140. Corresponding components for pressurizing the buffer volume in the buffer system 130 may include a compressor and pressure sensor loop to the buffer system 130 to maintain the pressure within the buffer 130 at some desirable pressure range. Other embodiments with reduced complexity and thus high reliability with respect to gas leakage, maintenance, and the like will be described with reference to FIGS. 2a-2c.

In other embodiments, the valve unit 170 may provide a bi-directional fluid flow, as long as the gas bottle 140 is connected to the input end 111. It is now assumed that the input valve unit 170 may be in its open state and may allow gas flow from the bottle 140 to the buffer system 130 so that the precursor gas may expand into the buffer volume until substantially the same pressure level is achieved within the bottle 140 and the buffer system 130. When the precursor gas contained in the bottle 140 is required for operating the ion source, since a specified implantation recipe is currently operated requiring the presence of the precursor gas, the output valve unit 180 may be transitioned from a closed state into a state providing a flow connection from the input end 121 to the output end 122 to establish a gas flow based on the pressure difference between the gas buffer system 130 and a process chamber within the ion source, which is typically held at vacuum condition. When the ion source 150 is operated in accordance with a process recipe that no longer requires the presence of the precursor gas of the bottle 140, the output valve unit 180 may be transitioned into its closed state, thereby discontinuing the gas flow from the buffer system 130 to the ion source 150. At the same time, the fluid connection between the buffer system 130 and the bottle 140 may be maintained so that the gas within the bottle 140 is still allowed to expand into the buffer system 130 even if the precursor gas is presently not required by the ion source 150. Consequently, even when the gas bottle 140 is moderately exhausted, thereby resulting in a reduced gas release rate of the adsorbent material, the expansion of the gas into the buffer system 130 is still maintained, whereas a substantially stable gas flow from the buffer system 130 to the ion source 150, although the pressure difference may slowly decrease, is maintained due to the moderately large gas volume contained in the buffer system 130, when the precursor gas is required by the ion source 150 in this operational stage. As a consequence, substantially stable gas flow conditions may be achieved with the supply system 100, while the utilization of the precursor gas initially contained in the bottle 140 is significantly increased. For example, up to approximately 95-99% of the precursor gas may be released from the adsorbent material, thereby significantly improving the cost of ownership while maintaining the down time of the ion source 150 at a low level and also reducing the risk of additional bottle change processes.

FIG. 1b schematically shows the supply system 100 connected to the ion source 150 in accordance with further illustrative embodiments. In these embodiments, the input conduit system 110 may comprise a plurality of individual conduits 113a, 113b, 113c, 113d with respective input ends 111a, 111b, 111c, 111d and corresponding output ends 112a, 112b, 112c, 112d. Similarly, the output conduit system 120 may comprise a plurality of individual output conduits 123a, 123b, 123c, 123d with respective input ends 121a, 121b, 121c, 121d. Moreover, the buffer system includes a plurality of buffer volumes 130a, 130b, 130c, 130d. Furthermore, the input valve unit 170 may be configured to allow an individual flow control of all of the conduits of the input conduit system 110. Analogously, the output valve unit 180 may be configured to allow an individual flow control of each of the individual conduits of the output conduit system 120. In some embodiments, a control unit 190 may be provided that is connected to the input valve unit 170 and the output valve unit 180 to control the fluid flow in conformity with a specified process recipe upon receipt of corresponding instructions from the ion implantation tool, or any other external source, such as an operator, and the like.

During the operation of the system 100 as shown in FIG. 1b, the input valve unit 170 may be controlled to provide fluid flow between respective bottles 140a, 140b, 140c, 140d and the buffer system 130 including the individual buffer volumes 130a, 130b, 130c, 130d, once it is confirmed that each of the bottles 140a, 140b, 140c, 140d is connected to the respective input end 111a, 111b, 111c, 111d. By appropriately setting the state of the output valve unit 180, a required precursor gas of one of the bottles 140a, 140b, 140c, 140d may be supplied to the ion source 150. If two or more precursor gases are required in the ion source 150 at the same time, the output valve unit 180 is advantageously configured to prevent a back flow from the output end 122 to the respective input ends 121a, 121b, 121c, 121d. This may be achieved by providing a respective number of check valves within the output valve unit 180. Regarding the individual buffer volumes 130a, 130b, 130c, 130d in combination with the individual bottles 140a, 140b, 140c, 140d, the same criteria apply as previously explained with reference to FIG. 1a, and thus the same advantages are achieved. It should also be noted that the bottles 140a, 140b, 140c, 140d may not necessarily contain different precursor gases. That is, two or more of the bottles 140a, 140b, 140c, 140d may contain the same type of gas, thereby allowing a long-term continuous operation of the ion source 150 without down time of the implantation tool after one of the two or more bottles is exhausted.

FIG. 2a schematically shows a supply system 200 according to further illustrative embodiments in which variable buffer volumes are used. The supply system 200 is connected to an ion source 250, which in turn is coupled to an accelerator tube of an ion implantation tool (not shown). The supply system 200 comprises an input conduit system 210 and an output conduit system 220, and a gas buffer system 230 provided between the input conduit system 210 and the output conduit system 220. An input end 211 of the conduit system 210 is configured to be connectable to a gas bottle 240 having mounted thereon a respective valve element 241. The system 200 may comprise an input valve unit 270 connected to control the fluid flow between the input end 211 and the gas buffer system 230. In the embodiment shown, the gas buffer system 230 may comprise two variable gas buffer volumes 230a and 230b, which are connected to the input conduit system 210 by respective individual conduits 213a, 213b having corresponding output ends 212a and 212b. Similarly, the output conduit system 220 comprises individual conduits 223a, 223b connected via an output valve unit 280 to respective input ends 211a, 211b, which in turn are connected to the respective buffer volumes 230a, 230b.

The buffer system 230 may further comprise measurement devices, such as pressure gauges 231a, 231b coupled to the respective buffer volumes 230a, 230b. The buffer volumes 230a, 230b are variable in the sense that the effective volume for receiving a precursor gas from the bottle 240 may be varied. For this purpose, appropriate means, such as moveable pistons, flexible membranes, or bladders and the like, may be used to vary the respective buffer volumes 230a, 230b. The change in volume may be controlled on the basis of measurement signals supplied by the respective measurement device 231a, 231b. It should be appreciated that in FIG. 2a two variable buffer volumes are shown, whereas in other embodiments, as already mentioned with respect to FIG. 1a, a single buffer volume may be provided. Moreover, in some embodiments, more than two variable buffer volumes may be provided for receiving different precursor gases or for receiving the same precursor gas. In the embodiment shown in FIG. 2a, the variable buffer volumes 230a, 230b may be changed in a mutually interrelated fashion, whereas, in other embodiments, the one or more variable buffer volumes may be varied individually. In FIG. 2a, a mechanical coupling between the buffer volume 230a and 230b is provided and may be accomplished, in one embodiment, by a moveable piston 232, so that, for instance, the buffer volume 230b may be reduced while, at the same time, the buffer volume 230a is increased. The moveable piston 232 may be configured to substantially avoid any gas flow between the volumes 230a and 230b, so that a certain degree of pressure regulation may be achieved by moving the piston 232. It should be noted that well-established drive assemblies, such as a plunger coupled to the piston 232, magnetic couplings, and the like, may be used for driving the moveable piston 232. For convenience, corresponding drive assemblies and mechanical components are not shown in FIG. 2a.

During operation of the supply system 200, the piston 232 may be moved to a certain position, for instance providing substantially the same initial volume for the buffer volumes 230a and 230b. During the process of connecting the bottle 240 to the input end 211, the valve unit 270 disconnects the buffer system 230 from the input end 211. Once the bottle 240 is connected to the input end 211, the valve unit 270 may be operated to allow fluid flow at least from the input end 211 to the respective buffer volumes 230a, 230b. The fluid flow may last until substantially the same pressure level is achieved in the buffer volumes 230a, 230b and the bottle 240. In case the operation of the ion source 250 requires the delivery of the type of precursor gas of the bottle 240, the output valve unit 280 including a valve element 281 may be configured such that fluid flow to the ion source 250 is established merely in one of the individual conduits 223a, 223b. For example, the output valve unit 280 may comprise check valves within the respective conduit 223a, 223b. In this case, by moving the piston 232 to decrease, for instance, the buffer volume 230b, a higher pressure may be produced therein while reducing the pressure in the volume 230a. The input valve unit 270 may also comprise corresponding check valves in the respective input conduit 213a and 213b. Consequently, a discontinuation of the fluid flow in the conduit 213b may be caused, while the gas flow from the bottle 240 to the buffer volume 230a is maintained or even promoted due to slight reduction in pressure within the volume 230a. At the same time, extraction of precursor gas from the volume 230a is substantially prevented due to the higher pressure provided by the volume 230b, which may prevent the gas from flowing through the corresponding check valve and into the output conduit 223a. It should be noted that in other embodiments the input valve unit 270 and the output valve unit 280 may comprise controllable valve elements in addition or alternatively to the check valves, thereby providing an enhanced flexibility in controlling the gas flow from the bottle 240 into the buffer system 230. If the gas flow from the volume 230b is continuously maintained due to the requirements of a specified process recipe processed in the ion source 250, the volume of the buffer volume 230b may be continuously reduced by correspondingly moving the piston 232, thereby providing the potential for maintaining a substantially constant pressure within the volume 230b. Consequently, the gas flow to the ion source 250 may be highly stable, irrespective of the pressure conditions within the bottle 240. At the same time, the pressure within the buffer volume 230a may be reduced due to the continuous increase in volume, thereby allowing a permanent release of gas from the bottle 240 as long as the pressure in the volume 230a is lower than the pressure in the bottle 240.

FIG. 2b schematically shows the supply system 200 in an operating state in which substantially all of the precursor gas contained in the volume 230b is delivered to the ion source 250 while still maintaining well-defined pressure conditions in the volume 230b. On the other hand, the volume 230a now contains a large portion of the precursor gas of the bottle 240 due to the increased volume. In this situation, the direction of movement of the piston 232 may be changed to increase the volume 230b and decrease the volume 230a, thereby reducing the pressure in the volume 230b and increasing the pressure in the volume 230a. When the pressure in the volume 230a exceeds the pressure in the volume 230b, the precursor gas may now be supplied from the volume 230a to the ion source 250, whereas the increasing volume 230b now receives the gas from the bottle 240. Although this operation may be performed substantially without interrupting the gas flow to the ion source 250, in highly sophisticated applications in which even short pressure fluctuations may not be tolerable, the change of the movement direction of the piston 232 may be performed in an operation stage of the ion source 250 in which the precursor of the bottle 240 is not required. After changing the direction of movement, the precursor gas may now be provided at a desired pressure level, and thus gas flow from the volume 230a by correspondingly controlling the motion of the piston 232, for instance on the basis of the results of the measurement device 231a.

FIG. 2c schematically shows the supply system 200 when the gas contents within the buffer volume 230a is substantially exhausted, yet still provides stable pressure conditions for the supply of the precursor gas to the ion source 250. Meanwhile, the supply of precursor gas from the bottle 240 to the volume 230b may efficiently continue, even if the pressure level in the bottle 240 is moderately low due to an imminent exhaustion of the bottle 240. By changing the direction of movement of the piston 232 again, a desired pressure level within the volume 230b may be established, although the piston 232 may have to travel a longer distance to the left owing to the reduced pressure level caused by the advanced degree of exhaustion of the bottle 240. At the same time, the significant increase in the volume 230a may now allow a further gas flow from the exhausted bottle 240 into the buffer volume 230a.

In this way, substantially stable pressure conditions may be maintained for the delivery of precursor gas to the ion source 250, while at the same time an excellent utilization of the precursor gas in the bottle 240 is accomplished.

As a result, the present invention provides a method and an apparatus for significantly enhancing the efficiency of a supply system for an ion source of an implantation tool. By providing a buffer volume between a gas bottle and the ion source, the fluid flow is significantly stabilized, while at the same time the utilization of the gas contents in the gas bottle is remarkably enhanced and down times for the implantation tool are maintained at a low level. Moreover, in some embodiments, the gas flow from the buffer volume to the ion source may be established on the basis of predetermined pressure conditions, while at the same time a fluid flow from the gas bottle to the buffer system may be maintained, even if the pressure in the bottle is less than the predetermined pressure.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A system, comprising:
an input conduit system adapted to be configured for fluid communication with one or more precursor gas bottles for an ion source of an ion implantation tool;
an output conduit system adapted to be configured for fluid communication with said ion source; and
a gas buffer system adapted to be configured for fluid communication with said input conduit system and said output conduit system.

2. The system of claim 1, further comprising at least one input valve unit between said at least one precursor gas bottle and said buffer system.

3. The system of claim 2, wherein said input valve unit comprises a check valve.

4. The system of claim 2, wherein said input valve unit comprises a first valve provided in said first input conduit and a second valve provided in said second input conduit.

5. The system of claim 1, further comprising at least one output valve unit provided within said output conduit system and configured to controllably discontinue a gas flow in said output conduit system.

6. The system of claim 1, wherein said input conduit system comprises a first input conduit and a second input conduit, said output conduit system comprises a first output conduit and a second output conduit and said buffer system comprises a first gas buffer and a second gas buffer, said first gas buffer connected to said first input conduit and said first output conduit, and said second gas buffer connected to said second input conduit and said second output conduit.

7. The system of claim 6, wherein said input valve unit comprises a first valve provided in said first input conduit and a second valve provided in said second input conduit.

8. The system of claim 2, wherein said gas buffer system comprises a first variable buffer volume and a second variable buffer volume.

9. The system of claim 8, wherein said first and second variable buffer volumes are fluidly decoupled.

10. The system of claim 9, wherein said first and second variable buffer volumes are each controllable on the basis of a pressure prevailing in each of said first and second variable buffer volumes.

11. The system of claim 8, wherein said first and second variable buffer volumes are coupled to said input conduit system by said input valve unit, said input valve unit configured to individually prevent a gas flow from said first variable buffer volume into said input conduit system and to individually prevent a gas flow from said second variable buffer volume into said input conduit system.

12. The system of claim 11, further comprising an output valve unit provided between said output conduit system and said first and second variable buffer volumes, said output valve unit configured to individually prevent a gas flow from said output conduit system into said first and second variable buffer volumes.

13. The system of claim 12, wherein said first and second variable buffer volumes are operatively coupled.

14. The system of claim 13, wherein said operative coupling is configured to increase said first variable buffer volume when said second variable buffer volume is reduced.

15. A system, comprising:
an ion implant tool comprising an ion source;
at least one precursor gas bottle containing a precursor gas to be supplied to said ion source; and
a buffer system for receiving said precursor gas from said at least one gas bottle prior to said precursor gas being supplied to said ion source.

16. The system of claim 15, further comprising at least one valve unit between said at least one precursor gas bottle and said buffer system.

17. A method of operating a supply system, the method comprising:
receiving in a first buffer volume a first precursor gas of an ion implantation tool from a first gas bottle; and
flowing said first precursor gas contained in said first buffer volume to an ion source of said ion implantation tool.

18. The method of claim 17, further comprising preventing a back flow of said first precursor gas from said first buffer volume to said first gas bottle when said first gas bottle is disconnected.

19. The method of claim 18, wherein said first precursor gas is permanently prevented from flowing back.

20. The method of claim 17, further comprising:
receiving in a second buffer volume a second precursor gas of said ion implantation tool from a second gas bottle; and
flowing said second precursor gas contained in said second buffer volume to said ion source of said ion implantation tool.

21. The method of claim 20, wherein, when flowing said second precursor gas to said ion source, flowing said first precursor gas to said ion source is discontinued while receiving said first precursor gas in said first buffer volume is continued.

22. The method of claim 17, further comprising discontinuing receiving said first precursor gas in said first buffer volume and receiving said first precursor gas in a second buffer volume while flowing said first precursor gas from said first buffer volume to said ion source.

23. The method of claim 22, further comprising reducing said first buffer volume to control a pressure therein.

24. The method of claim 23, further comprising increasing said second buffer volume to maintain a desired pressure difference between said second buffer volume and said first bottle.

25. The method of claim 24, further comprising discontinuing flowing said first precursor gas from said first buffer volume to said ion source and increasing said first buffer volume to establish a desired pressure difference between said first buffer volume and said first gas bottle to allow gas flow from said first gas bottle to said first buffer volume.

26. The method of claim 24, further comprising decreasing said second buffer volume to adjust a pressure therein to allow gas flow from said second buffer volume to said ion source.
